(19) United States
(12) Patent Application Publication
(10) Pub. No.: US 2010/0204936 A1
(43) Pub. Date: Aug. 12, 2010

(54) Probing Electrode/Solution Interfaces

(75) Inventors: Niklas K. Hansson, Goteborg (SE); Niklas Olofsson, Molndal (SE); Anders O. Lundgren, Varberg (SE); Bjorn O. Lundgren, Goteborg (SE); Patrik C. Nordberg, Goteborg (SE)

Correspondence Address: FISH & RICHARDSON P.C., PO BOX 1022, MINNEAPOLIS, MN, 55440-1022, US

(73) Assignee: Midorion AB, Goteborg (SE)

(21) Appl. No.: 12/369,271

(22) Filed: Feb. 11, 2009

(51) Int. Cl. G01R 27/26; G06F 19/00; G01R 27/08

(52) U.S. Cl. 702/65; 324/690; 324/724

(57) ABSTRACT

Systems and techniques for probing interfaces between electrodes and conductive solutions. In one aspect, devices can include a time variable source of power configured to output power that varies in time over a pair of output conductors, an electrode connected to a first of the conductors, an extrinsic inductive impedance connected between the pair of output conductors, and an impedance sensor connected to one or both of the output conductors and configured to measure net impedance between the pair of output conductors based on a known current or voltage output by the time variable power output. The measured net impedance includes the extrinsic inductive impedance and an impedance of the interface. The electrode is configured to be submersed in a conducting solution and form an interface with the conducting solution.

### BACKGROUND

This specification relates to probing interfaces between electrodes and conductive solutions.

Many solutions are conductive. For example, aqueous ionic solutions are generally conductive in their bulk due to the movement of ions through the solution. Metallic and other conductors, as well as semiconductors, can be used as electrodes and physically contacted with conductive solutions to form an electrode/solution interface.

The electrode/solution interface encompasses the volume in both the electrode and the solution where the properties of the electrode and the solution differ from the properties of the bulk. In the context of metallic electrodes, the electrode/solution interface does not extend meaningfully into the electrode but rather is confined to the outer surface.

The structure of electrode/solution interfaces can be impacted by a number of different parameters, including the bulk and interfacial composition of the electrode and the solution, the application of an external bias, the adsorption of species at the interface, and changes in these and other parameters over time.

The structure of electrode/solution interfaces can be probed using electrochemical impedance spectroscopy (EIS). In EIS, the real and imaginary conductivity of the electrode/solution interface is probed as a function of frequency. In discussing EIS, it is traditional to refer to the inverse of this conductivity, namely, the real and imaginary impedance of the electrode/solution interface. Much like the structure of the electrode/solution interface, the impedance of the electrode/solution interface can be impacted by a number of different parameters, including the bulk and interfacial composition of the electrode and the solution, the application of an external bias, the adsorption of species at the interface, and changes in these and other parameters over time.

### SUMMARY

This specification describes systems and techniques for probing electrode/solution interfaces. In one aspect, devices can include a time variable source of power configured to output power that varies in time over a pair of output conductors, an electrode connected to a first of the conductors, an extrinsic inductive impedance connected between the pair of output conductors, and an impedance sensor connected to one or both of the output conductors and configured to measure net impedance between the pair of output conductors based on a known current or voltage output by the time variable power output. The measured net impedance includes the extrinsic inductive impedance and an impedance of the interface. The electrode is configured to be submersed in a conducting solution and form an interface with the conducting solution.

This and other aspects can include one or more of the following features. A frequency of the time variable power output can be variable. The device can also include a reference electrode and a voltage supply connected to bias the electrode relative to the reference electrode. The device can also include a potentiostat to bias the electrode. The device can also include a controller configured to perform operations. The operations can include setting a frequency of the time variable power output to the two or more frequencies and receiving, from the impedance sensor, information characterizing the impedance of the time variable power output at the two or more frequencies. The operations of the controller can also include modeling impedance of the interface between the electrode and the conducting solution considering the impedance between the electrode and the conducting solution to be in parallel with impedance of the extrinsic inductive impedance, characterizing a capacitive component or a resistive component of the impedance between the electrode and the conducting solution using the impedance between the electrode and the conducting solution, and outputting a characterization of the capacitive component. The operations can also include outputting a characterization of the capacitive component.

The time variable source of power can include a voltage or current source configured to output a voltage or a current at frequencies below 100 kHz. The time variable source of power can include a current source programmable to output a known current. The impedance sensor comprises a voltammeter connected to sense a voltage resulting from a flow of the time variable current through the impedance. The time variable source of power can include a voltage source programmable to output a known voltage. The impedance sensor can include a voltammeter connected to sense a voltage across the impedance.

The device can also include the conducting solution and a contact between a second of the conductors and the solution. The electrode can be submersed in the conducting solution. The measured impedance can exclude a bulk solution capacitance of the conducting solution.

In another aspect, systems include a display screen and one or more data processing devices programmed to interact with the display screen and to perform operations. The operations include receiving results of probing an electrode/solution interface using an electrical signal, modeling impedance of the electrode/solution interface considering the impedance of the electrode/solution interface to be in parallel with impedance of the extrinsic inductive impedance, characterizing a capacitive component or a resistive component of the electrode/solution interface using the impedance of the electrode/solution interface, and displaying a characterization of the capacitive component or the resistive component of the electrode/solution interface on the display screen. The electrode/solution interface was in parallel with an extrinsic inductive impedance during the probing.

This and other aspects can include one or more of the following features. The operations can include probing the electrode/solution interface. The probing can include applying a potential referenced to a reference electrode to the electrode forming the electrode/solution interface. Modeling impedance of the electrode/solution interface can include ignoring bulk solution capacitance of the solution forming the electrode/solution interface. The results of probing can include results characterizing impedance of the electrode/solution interface at two or more frequencies of the electrical signal and/or results characterizing a voltage across the electrode/solution interface in parallel with the extrinsic inductive impedance when a known time varying current is driven therethrough.

Other embodiments of this aspect include corresponding methods, devices, and computer programs recorded on computer storage devices, each configured to perform the operations of the data processing devices.

In another aspect, methods include receiving results of probing an interface between an electrode and a conducting solution, the results including measurements of an impedance of the interface in parallel with an extrinsic inductive impedance, characterizing a capacitive component or a resistive component of the interface using a model that includes the impedance of the interface in parallel with an inductance of the extrinsic inductive impedance, and outputting a characterization of the capacitive component or the resistive component.

This and other aspects can include one or more of the following features. Characterizing the capacitive component or the resistive component of the interface can include ignoring a bulk solution capacitance of the conducting solution. The results of probing the interface can include measurements of the impedance when a known current flows through the interface in parallel with the extrinsic inductive impedance and/or measurements of the impedance with the electrode held in the conducting solution at a voltage relative to a reference electrode in the conducting solution.

Other embodiments of this aspect include corresponding systems, devices, and computer programs recorded on computer storage devices, each configured to perform the operations of the methods.

The details of one or more implementations are set forth in the accompanying drawings and the description below. Other features and advantages will be apparent from the description and drawings, and from the claims.

### DESCRIPTION OF DRAWINGS

FIGS. 1 and 2 are schematic representations of systems for probing electrode/solution interfaces.

FIGS. 3, 4, and 6 are a schematic representations of impedance models of systems that include electrode/solution interfaces.

FIG. 5 is a schematic representation of a pair of interdigitated electrodes that can be used in systems that include electrode/solution interfaces.

FIGS. 7 and 8 are schematic representations of measurement systems for probing electrode/solution interfaces in systems such as the systems shown in FIGS. 1 and 2.

FIG. 9 is a schematic representation of an active filter of a measurement system for probing electrode/solution interfaces.

FIG. 10 is a schematic representation of an active filter of a measurement system for probing electrode/solution interfaces.

FIG. 11 is a schematic representation of a passive filter of a measurement system for probing electrode/solution interfaces.

FIG. 12 is a schematic representation of a passive filter of a measurement system for probing electrode/solution interfaces.

FIG. 13 is a schematic representation of an active filter of a measurement system for probing electrode/solution interfaces.

FIG. 14 is a schematic representation of a passive filter of a measurement system for probing electrode/solution interfaces.

FIG. 15 is a graph that presents results of probing an electrode/solution interface.

FIGS. 16, 17 are schematic representations of test specimens of measurement systems for probing electrode/solution interfaces in systems such as the systems shown in FIGS. 1 and 2.

FIG. 18 is a schematic representation of an array of interdigitated electrodes that can be used to probe electrode/solution interfaces in systems such as the systems shown in FIGS. 1 and 2.

Like reference symbols in the various drawings indicate like elements.

### DETAILED DESCRIPTION

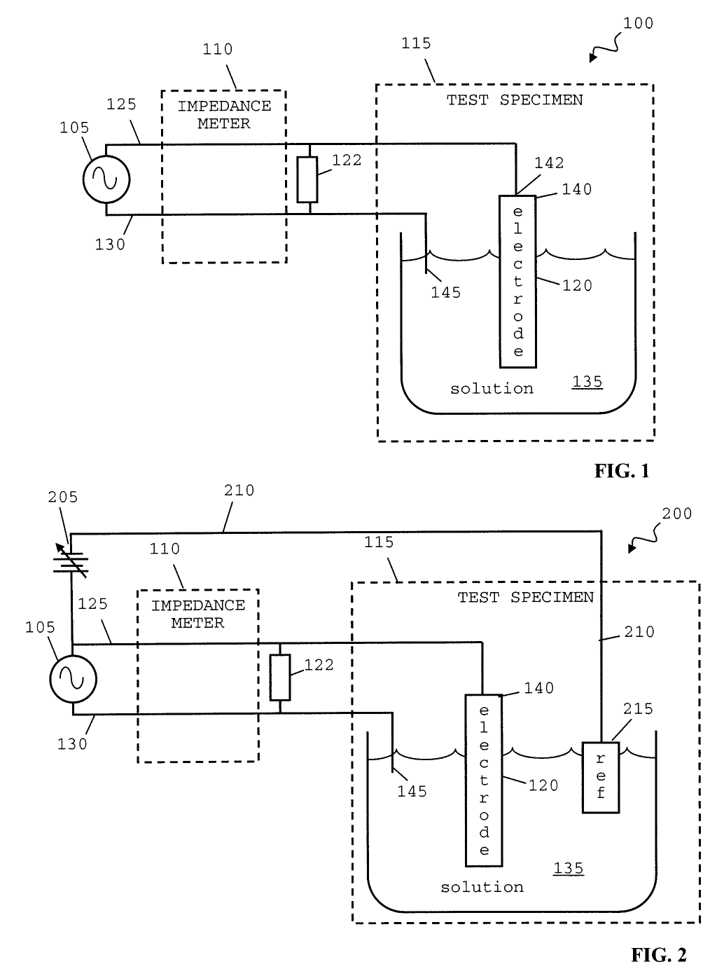

FIG. 1 is a schematic representation of a system 100 for probing electrode/solution interfaces. System 100 includes a time variable power source 105, an impedance measurement device 110, and a test specimen 115 in which one or more electrode/solution interfaces 120 to be probed are formed. The electrode/solution interface 120 in test specimen 115 is in parallel with an extrinsic inductive impedance 122 that facilitates probing of the electrode/solution interfaces 120, as discussed further below.

Time variable power source 105 is a source of electrical or other power. The output of time variable power source 105 varies with time (e.g., is an AC signal). For example, time variable power source 105 can be a current or voltage source that presents a sinusoidal output across conductors 125, 130. In some implementations, the frequency of the time variable output of time variable power source 105 can also change. For example, time variable power source 105 can supply a discrete or continuous range of frequencies under the control of a control processor. In some implementations, time variable power source 105 can supply a group of between 5 and 20 or so discrete sinusoidal currents or voltages.

The frequency of the output of time variable power source 105 can be selected to probe components of the impedance of the electrode/solution interface. Thus, the frequency of the output of time variable power source 105 can be low enough that the bulk capacitance (of the solution) between electrodes does not impact the observed net impedance. In practical terms, the electrode/solution interface is generally probed at frequencies below 100 kHz or so. In probing electrode/solution interfaces that include biomolecular species, frequencies below 10 kHz or so, or 1 kHz or so, can be used.

In some implementations, a relatively small range of frequencies (e.g., a range of between 500 Hz and 10000 Hz) can be used to probe an electrode/solution interface. For example, the output of time variable power source 105 can be stepped to between 10 and 20 different frequencies, each separated by, e.g., 50 Hz to 500 Hz. The range of frequencies can be chosen to encompass the frequency where the net impedance between conductors 125, 130 is at its highest. For example, the frequency of the highest net impedance can be selected to be approximately in the middle of the range of frequencies. Using of a relatively small range of frequencies allows components of the impedance of the electrode/solution interface to be probed quickly. This allows impedance measurements to be resolved in time and responsive to dynamic situations where the characteristics of the electrode/solution interface change relatively rapidly. An example of probing in such a dynamic situation, namely, an electrode/solution interface that is found in a flow cell, is discussed further below.

In some implementations, the frequency of the output of time variable power source 105 does not change. Rather, the magnitude of extrinsic inductive impedance 122 changes so that the frequency of the highest net impedance shifts with time. With the magnitude of extrinsic inductive impedance 122 changing, the net impedance will also change in a manner that allows the components of the impedance of the electrode/solution interface to be characterized.

In some implementations, both the frequency of the output of time variable power and the magnitude of extrinsic inductive impedance 122 change. With both the magnitude of extrinsic inductive impedance 122 and the frequency of the output of time variable power source 105 changing, the net impedance can be measured rapidly and components of the impedance of the electrode/solution interface can be characterized.

Impedance measurement device 110 is one or more devices configured to measure the net impedance between conductors 125, 130, which in turn can be used to characterize components of the reactive impedance, the real impedance, or both the reactive and real impedances of one or more electrode/solution interfaces in test cell 115. Impedance measurement device 110 can measure net impedance in a number of different ways. For example, impedance measurement device 110 can be an ammeter that measures current flow in one or both of conductors 125, 130, either directly or with a shunt or other resistor. As another example, impedance measurement device 110 can be a voltmeter that measures the voltage between conductors 125, 130, e.g., using a voltage divider. As discussed below, impedance measurement device 110 can generate an output signal that characterizes the net impedance of test cell 115. For example, impedance measurement device 110 can supply measurement results to a control processor.

Test specimen 115 includes one or more electrode/solution interfaces 120 formed between one or more electrically conductive solutions 135 and one or more electrodes 140. Solution 135 can be an aqueous or other solution. In general, solution 135 conducts electricity in bulk, e.g., through the movement and/or reaction of ionic species. In some implementations, solution 135 can include biomolecular species such as proteins, nucleic acids, and lipids. Empirical results of probing solutions 135 that include biomolecular species are given below.

Electrode 140 can be, e.g., a conductive electrode or a semiconductive electrode. Electrode 140 can be, e.g., a solid (e.g., metallic) electrode, a liquid (e.g., mercury) electrode, a gel or other colloidal electrode, or combinations thereof.

Electrode/solution interface 120 is formed at the contact between solution 135 and electrode 140. Electrode/solution interface 120 generally extends into solution 135 in that the properties of solution 135 in the immediate vicinity of electrode 140 differ from the properties of the bulk of solution 135. For example, an electrical double layer generally forms within solution 135 in the vicinity of electrode 140. As another example, both charged and uncharged species may preferentially concentrate in the vicinity of electrode 140, e.g., due to specific and non-specific interactions with the surface of electrode 140 or with other molecules at electrode/solution interface 120.

In some implementations, electrode/solution interface 120 can also extend into electrode 140, such as when electrode 140 is made from a semiconductor. However, electrode/solution interface 120 is generally confined to the surface of electrode 140 when electrode 140 is a metallic conductor.

Electrode/solution interface 120 has an electrical impedance that can be probed using system 100. The impedance of electrode/solution interface 120 can include both real (e.g., resistive) and reactive components. The impedance of electrode/solution interface 120 is a function of a number of different factors, including the bulk and interfacial composition of electrode 140 and solution 135, the application of an external bias to electrode 140, the adsorption of species at the interface 120, and changes in these and other parameters over time.

As shown, conductor 125 contacts electrode 140 at a contact 142 and conductor 130 contacts solution 135 at a contact site 145. Contact site 145 can be any of a number of different electrical connections to solution 135. For example, contact site 145 can be the electrode/solution interface of a counter electrode. In such implementations, the counter electrode/solution interface impedance is generally lower than the impedance of electrode/solution interface 120. For example, the area of a counter electrode contact site 145 can be made much larger than the area of electrode/solution interface 120. As another example, electrode/solution interface 120 and contact site 145 can each be electrodes of an interdigitated electrode pair, as discussed further below.

Extrinsic inductive impedance 122 is one or more devices that introduce inductance into system 100. The inductance in extrinsic inductive impedance 122 opposes a change in current. Inductive impedance 122 is extrinsic in that it is not an inherent part of other constituents of system 100, but rather has been intentionally added. Extrinsic inductive impedance 122 can be formed using a fixed or a variable inductance, such as a choke coil or a gyrator. The magnitude of extrinsic inductive impedance 122 can be tailored to the impedance of electrode/solution interface 120 to facilitate probing of electrode/solution interface 120. In some implementations, the tailoring of extrinsic inductive impedance 122 can also consider the impedance of contact site 145. In some implementations, extrinsic inductive impedance 122 can be tailored to match to the real and imaginary impedance between conductors 125, 130 through solution 135. In particular, for a given frequency range in the power output by time variable power source 105, the impedance of extrinsic inductive impedance 122 can be made, e.g., to be of the same order of magnitude as the net impedance between conductors 125, 130 through solution 135. Such tailoring of extrinsic inductive impedance 122 can be done, e.g., before or while electrode 140 is in contact with solution 135.

FIG. 2 is a schematic representation of a system 200 for probing components of the impedance of electrode/solution interfaces. In addition to time variable power source 105, impedance measurement device 110, test specimen 115, and extrinsic inductive impedance 122, system 200 includes a voltage supply 205. Voltage supply 205 is a voltage source that can provide voltages that change relatively slowly compared to the rate of change of time variable power source 105. Voltage supply 205 is thus not limited to supplying a only a single voltage. Rather, voltage supply 205 can supply a variety of slowly changing or unchanging (e.g., DC) voltages under the control of a control processor, as discussed further below.

Voltage supply 205 is connected to provide the voltage between a conductor 210 and conductor 125. Conductor 210 can be arranged to conduct the applied potential to a reference electrode 215 that is in contact with solution 135 in test specimen 115. This arrangement can place electrode 140 at a desired potential relative to the potential of reference electrode 215 in solution 135.

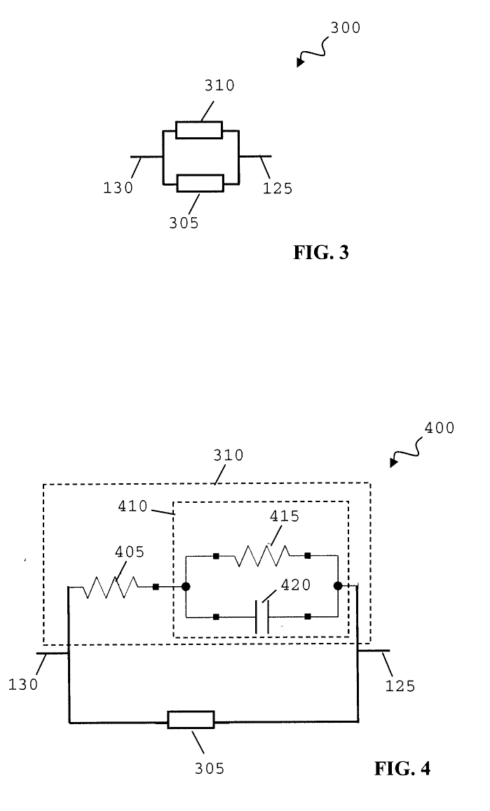

FIG. 3 is a schematic representation of a net impedance model 300 of systems such as systems 100, 200. Net impedance model 300 can be used in analyzing the results of probing electrode/solution interface 120, e.g., to characterize real and imaginary components of the impedance of an electrode/solution interface. Net impedance model 300 includes an inductive impedance 305 in parallel with an impedance 310 that together form the net impedance. Inductive impedance 305 approximates the impedance of extrinsic inductive impedance 122 in systems such as systems 100, 200. Inductive impedance 305 can include both reactive and real components to account for deviations from ideality in extrinsic inductive impedance 122.

Impedance 310 includes both the real and imaginary components of the impedance between conductors 125, 130 through solution 135. Impedance 310 can thus include, e.g., the impedance of electrode/solution interface 120, the impedance of contact site 145, as well as the bulk impedance of solution 135 between electrode/solution interface 120 and contact site 145. In some implementations, one or more of these impedances can be ignored, as discussed further below. Impedance 310 does not include the bulk capacitance of the solution between electrodes 140 and contact site 145.

Models such as model 300 can be used to analyze the results of probing electrode/solution interface 120. In particular, the impedance of electrode/solution interface 120 can be analyzed to determine the behavior of species in solution 135, treating systems such as systems 100, 200 as an equivalent circuit that is analyzed in accordance with linear system analysis techniques. In such an equivalent circuit, the impedance Z of model 300 can be treated as:

$${Z}_{NET} = {Z}_{305} ‖ {Z}_{310} = \frac{{Z}_{305} {Z}_{310}}{{Z}_{305} + {Z}_{310}} \qquad Equation 1$$

The analysis can be performed by one or more data processing devices (such as a digital computer) that perform operations in accordance with one or more sets of machine-readable instructions (such as software). The instructions can be stored in tangible data storage devices, including magnetic discs and optical media. The results of the analysis can be presented, e.g., by physical transformation of display elements of a display device or of memory elements in a data storage device.

FIG. 4 is a schematic representation of a net impedance model 400 of systems such as systems 100, 200. Net impedance model 400 can be used in analyzing the results of probing electrode/solution interface 120, e.g., to characterize real and imaginary components of the impedance of an electrode/solution interface. Net impedance model 400 includes inductive impedance 305 in parallel with impedance 310 that together form the net impedance. Impedance 310 includes a bulk solution impedance 405 that is in series with an interfacial impedance 410. Bulk solution impedance 405 is the bulk impedance of solution 135 between electrode/solution interface 120 and contact site 145 and can be approximated by a pure resistance, as shown.

Interfacial impedance 410 is the impedance of impedance of electrode/solution interface 120. Interfacial impedance 410 can be approximated by an interfacial resistance 415 in parallel with an interfacial capacitance 420. Interfacial resistance 415 can account for different aspects of the impedance of electrode/solution interface 120, including, e.g., the charge transfer resistance of electrode/solution interface 120, the Warburg impedance of electrode/solution interface 120, the resistance of electrode/solution interface 120, the ohmic resistance to charge transfer, e.g., across dielectric species at electrode/solution interface 120, and the like. Interfacial capacitance 420 can account for different aspects of the capacitance of electrode/solution interface 120, including, e.g., the double layer capacitance of electrode/solution interface 120, the capacitance across dielectric species at electrode/solution interface 120, and the like.

Model 400 does not consider the impedance of contact site 145 and is hence particularly appropriate for modeling systems in which the impedance of contact site 145 is negligible compared to bulk solution impedance 405 and interfacial impedance 410. For example, model 400 can be used to model systems in which contact site 145 is a large surface area counter electrode. Model 400 also does not consider the bulk capacitance of the solution between electrodes 140 and contact site 145.

Model 400 can be used to analyze the results of probing electrode/solution interface 120, treating systems such as systems 100, 200 as an equivalent circuit. In such an equivalent circuit, the impedance Z of model 400 can be treated as per Equation 1 above, where:

$$\begin{matrix}{Z}_{310} = {Z}_{405} + {Z}_{410} & Equation 2 \\ {Z}_{410} = {R}_{415} ‖ {Z}_{420} = \frac{{R}_{415} {Z}_{420}}{{R}_{415} + {Z}_{420}} & Equation 3\end{matrix}$$

In some implementations, the reactive impedances can be expressed using idealized an idealized capacitance C₄₂₀, inductance L₁₂₂, and resistance (of inductive impedance 122) L₁₂₂. Resistance L₁₂₂ can represent the finite resistance of a real extrinsic inductive impedance 122.

$$\begin{matrix}{Z}_{420} = \frac{1}{j ω {C}_{420}} & Equation 4 \\ {Z}_{305} = j ω {L}_{122} + {R}_{122} & Equation 5\end{matrix}$$

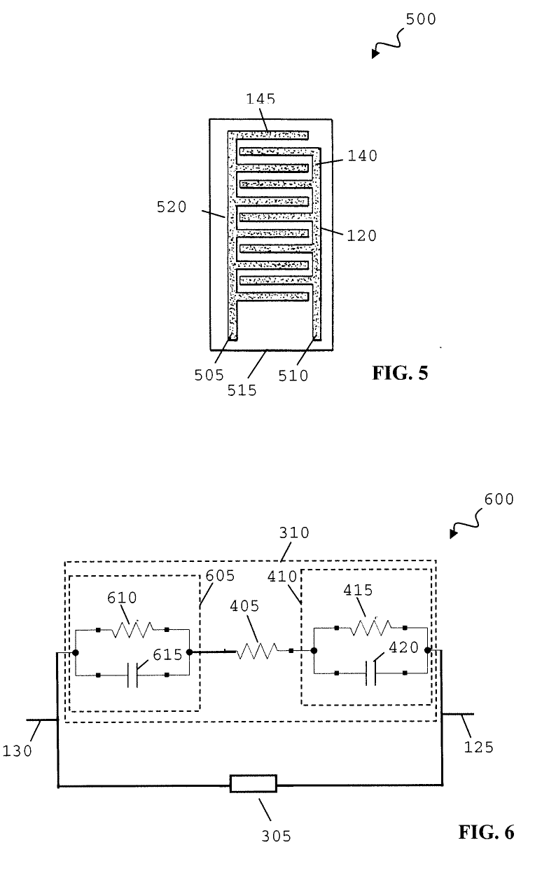

FIG. 5 is a schematic representation of a pair 500 of interdigitated electrodes 505, 510 that can be used in systems such as systems 100, 200. Interdigitated electrodes 505, 510 can be thin metallic film electrodes that are formed on an insulating substrate 515 using, e.g., lithographic techniques. For example, electrodes 505, 510 can be made from gold and approximately 200 nm thick, 10 □m wide, and include 20 fingers spaced 10 □m apart. In some implementations, electrode 505 is matched to electrode 510 in that electrode 505 is made from the same material and has generally the same dimensions as electrode 510. In some implementations, electrodes 505, 510 can be fabricated from materials that support surface plasmons on a substrate 515 that transmits electromagnetic radiation or electrons capable of exciting the surface plasmons. For example, gold electrodes 505, 510 can be fabricated on a glass substrate 515.

In system 100, electrode 505 can act as electrode 140 and electrode 505 can act as a counter electrode forming contact site 145. Contact site 145 can thus form a electrode/solution interface 520 with solution 135. In implementations in which electrode 505 is matched to electrode 510, the impedance of electrode/solution interface 520 can be comparable to the impedance of electrode/solution interface 120 in that the impedance of electrode/solution interface 520 cannot be ignored in analyzing the results of probing systems such as systems 100, 200.

FIG. 6 is a schematic representation of a net impedance model 600 of systems such as systems 100, 200. Net impedance model 600 can be used in analyzing the results of probing electrode/solution interface 120, e.g., to characterize real and imaginary components of the impedance of an electrode/solution interface. Net impedance model 300 includes inductive impedance 305 in parallel with impedance 310 that together form the net impedance. Impedance 310 includes a bulk solution impedance 405 that is in series with interfacial impedance 410 and an interfacial impedance 605. Interfacial impedance 605 is the impedance of a contact site 145 such as electrode/solution interface 520 in cases where the impedance of a contact site 145 is not negligible in comparison with the impedance of electrode/solution interface 120.

Interfacial impedance 605 can be approximated by an interfacial resistance 610 in parallel with an interfacial capacitance 615. Interfacial resistance 610 can account for different aspects of the impedance of contact site 145, including, e.g., the charge transfer resistance at contact site 145, the Warburg impedance at contact site 145, the resistance at contact site 145, the ohmic resistance to charge transfer, e.g., across dielectric species at contact site 145, and the like. Interfacial capacitance 615 can account for different aspects of the capacitance at contact site 145, including, e.g., the double layer capacitance at contact site 145, the capacitance across dielectric species at contact site 145, and the like.

Model 600 can be used to analyze the results of probing electrode/solution interface 120, treating systems such as systems 100, 200 as an equivalent circuit. In such an equivalent circuit, the impedance Z of model 600 can be treated as per Equation 1 above, where:

$$\begin{matrix}{Z}_{310} = {Z}_{605} + {Z}_{405} + {Z}_{410} & Equation 6 \\ {Z}_{605} = {R}_{610} ‖ {Z}_{615} = \frac{{R}_{610} {Z}_{615}}{{R}_{610} + {Z}_{615}} & Equation 7\end{matrix}$$

In some implementations, the reactive impedances can be expressed using idealized an idealized capacitance C₆₁₅.

$${Z}_{615} = \frac{1}{j ω {C}_{615}} \qquad Equation 8$$

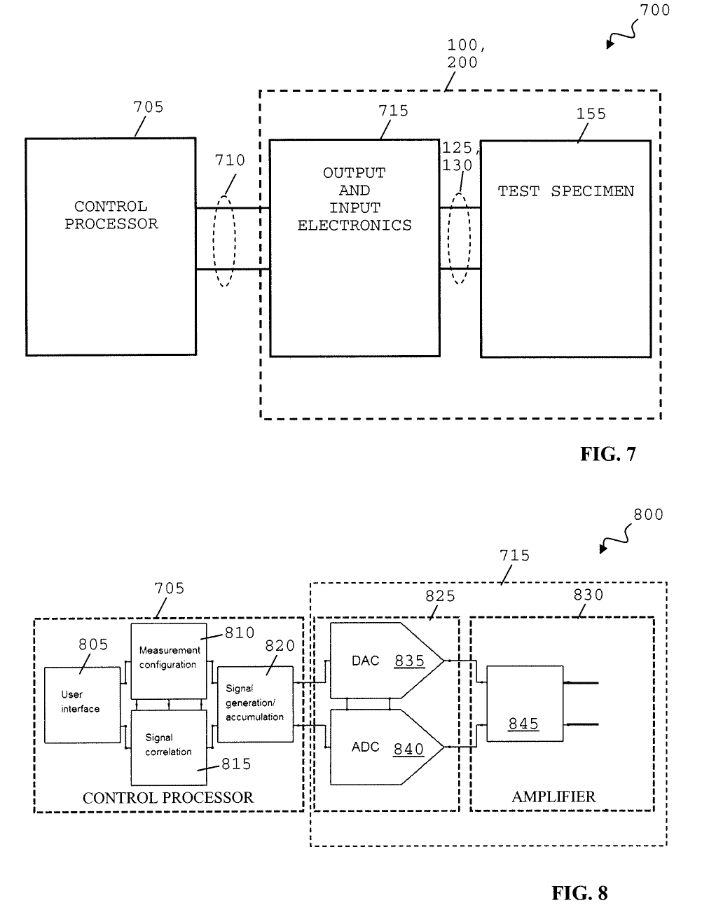

FIG. 7 is a schematic representation of a measurement system 700 for probing electrode/solution interfaces in systems such as systems 100, 200. Measurement system 700 includes a control processor 705 that interacts with systems such as systems 100, 200 over a communication path 710.

Control processor 705 can include one or more data processing devices that perform operations in accordance with one or more sets of machine-readable instructions. For example, control processor 705 can be a personal computer that executes software. The operations can include, e.g., controlling time variable power source 105 to supply power, controlling voltage supply 205 to bias an electrode 140 relative to a reference electrode 215, receiving impedance measurement results from impedance measurement device 110, interacting with a user, and analyzing the impedance measurement results in accordance with one or more of models 300, 400, 600. The analysis of the impedance measurement results in accordance with models 300, 400, 600 can yield values for the various impedances in models 300, 400, 600.

As shown, systems such as systems 100, 200 can be described as including output and input electronics 715 and test specimen 155 connected by conductors 125, 130. Output and input electronics 715 can include, e.g., time variable power source 105, impedance measurement device 110, extrinsic inductive impedance 122, with or without voltage supply 205.

FIG. 8 is a schematic representation of a measurement system 800 for probing electrode/solution interfaces in systems such as systems 100, 200. Measurement system 800 can be connected to a test specimen 155 (not shown). Control processor 705 in measurement system 800 includes a user interface module 805, a measurement configuration module 810, a signal correlation module 815, and a signal generation/accumulation module 820.

User interface module 805 can be implemented on a data processing device to interact with a user. The user interaction can include the receipt of instructions for configuring the probing of an electrode/solution interface and the presentation of results. For example, in some implementations, user interface module 805 can receive user interaction that configures sinusoidal voltages or current supplied by time variable power source 105, the voltages supplied by voltage supply 205, and/or the model used in analyzing impedance measurement results. As another example, user interface module 805 can present the impedance measurement results received from impedance measurement device 110. The results can be present in raw form and/or after analysis.

Measurement configuration module 810 can exchange information with user interface module 805, signal correlation module 815, and signal generation/accumulation module 820 for configuring the parameters for probing electrode/solution interfaces.

Signal correlation module 815 can exchange information with user interface module 805, measurement configuration module 810, and signal generation/accumulation module 820 for analyzing the results of probing electrode/solution interfaces. For example, signal correlation module 815 can analyze the results of probing electrode/solution interfaces using linear systems theory in accordance with one or more of models 300, 400, 600.

Signal generation/accumulation module 820 can exchange information with user interface module 805 and measurement configuration module 810 for communicating with input and output electronics 715. For example, signal generation/accumulation module 820 can format outgoing communications and accumulate incoming measurement results for subsequent analysis.

In the illustrated implementation, output and input electronics 715 includes an analog/digital interface stage 825 and an amplification stage 830. Analog/digital interface stage 825 can include a digital to analog converter 835 and an analog to digital converter 840. Digital to analog converter 835 converts digital signals received from control processor 705 into analog format. Analog to digital converter 840 converts analog signals (e.g., impedance measurement results) received from amplification stage 830 into digital format.

Amplification stage 830 can include one or more analog amplifiers 845 for amplifying analog signals received from digital to analog converter 835 and intended for other portions (not shown) of the output and input electronics 715 in systems such as systems 100, 200. Analog amplifier(s) 845 can also amplify analog signals received from other portions (not shown) of the output and input electronics 715 in systems such as systems 100, 200 and intended for analog to digital converter 840.

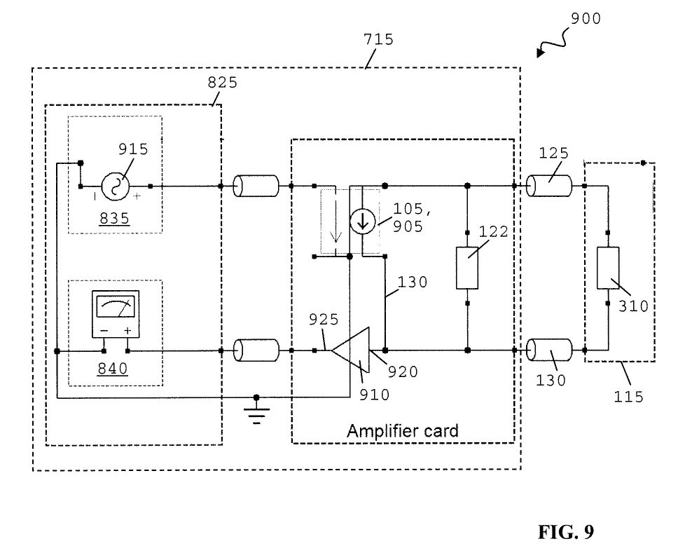

FIG. 9 is a schematic representation of an active filter 900 of a measurement system for probing electrode/solution interfaces in systems such as system 100. In addition to other elements, active filter 900 includes a current source 905 and a voltage sense amplifier 910. Current source 905 acts as time variable power source 105 and outputs a known time variable current over conductor 130 in response to a time varying signal 915 received from digital to analog converter 835. An input 920 of voltage sense amplifier 910 is connected to conductor 130 and amplifies the potential thereon. The current output by current source 905 splits between extrinsic inductive impedance 122 and impedance 310, according to the relationship between the magnitudes thereof. The potential at input 920 of voltage sense amplifier 910 thus reflects the relationship of both the real and imaginary impedance between conductors 125, 130 through solution 135 (i.e., impedance 310) to extrinsic inductive impedance 122.

Voltage sense amplifier 910 outputs an analog voltage signal on an output 925. The output voltage is digitized by analog to digital converter 840 and can be output to control processor 705 (not shown).

In the illustrated implementation, amplification stage 830 is implemented on single card of a digital data processing device and includes extrinsic inductive impedance 122. This is not necessarily the case. For example, extrinsic inductive impedance 122 can be isolated from output and input electronics 715, e.g., using a magnetic shield.

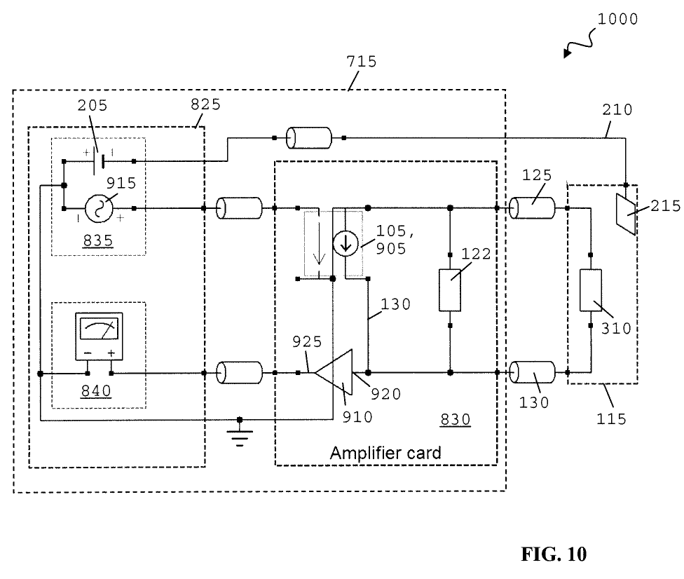

FIG. 10 is a schematic representation of an active filter 1000 of a measurement system for probing electrode/solution interfaces in systems such as system 200. In particular, active filter 1000 includes voltage supply 205, conductor 210, and reference electrode 215 so that electrode 140 can be placed at a desired potential relative to the potential of reference electrode 215.

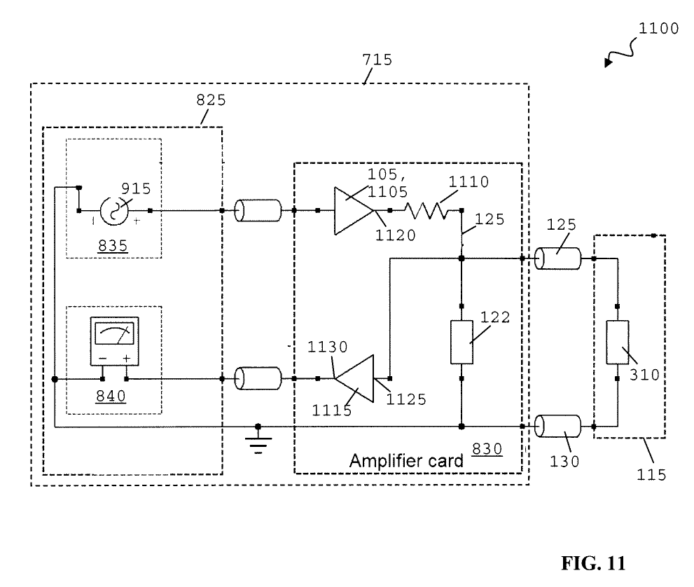

FIG. 11 is a schematic representation of a passive filter 1100 of a measurement system for probing electrode/solution interfaces in systems such as system 100. In addition to other elements, passive filter 100 includes a voltage source amplifier 1105, a sense resistor 1110, and a voltage sense amplifier 1115. Voltage source amplifier 1105 acts as time variable power source 105 and outputs a time variable voltage at an output 1120 in response to a time varying signal 915 received from digital to analog converter 835.

Sense resistor 1110 connects output 1120 to conductor 125. Sense resistor 1110 acts as a voltage divider and is in series with the parallel arrangement of extrinsic inductive impedance 122 and impedance 310 between conductors 125, 130. Sense resistor 1110 has a known impedance and can be selected based on the expected impedance between conductors 125, 130 through solution 135. For example, in common aqueous solutions contacted by metallic gold electrodes having a surface area of approximately 0.002 cm², sense resistor 1110 can be, e.g., between 10 and 1000 kohm. Conductor 130 acts as a return path to digital to analog converter 835. Thus, the voltage dropped across sense resistor 1110 reflects the relationship between the real and imaginary impedance between conductors 125, 130 through solution 135 (i.e., impedance 310) and extrinsic inductive impedance 122.

Voltage sense amplifier 1115 has an input 1125 that is connected to conductor 125 and amplifies the potential thereon. The amplified voltage is output on an output 1130. The output voltage is digitized by analog to digital converter 840 and can be output to control processor 705 (not shown).

In the illustrated implementation, amplification stage 830 is implemented on single card of a digital data processing device and includes extrinsic inductive impedance 122. This is not necessarily the case. For example, extrinsic inductive impedance 122 can be isolated from output and input electronics 715, e.g., using a magnetic shield.

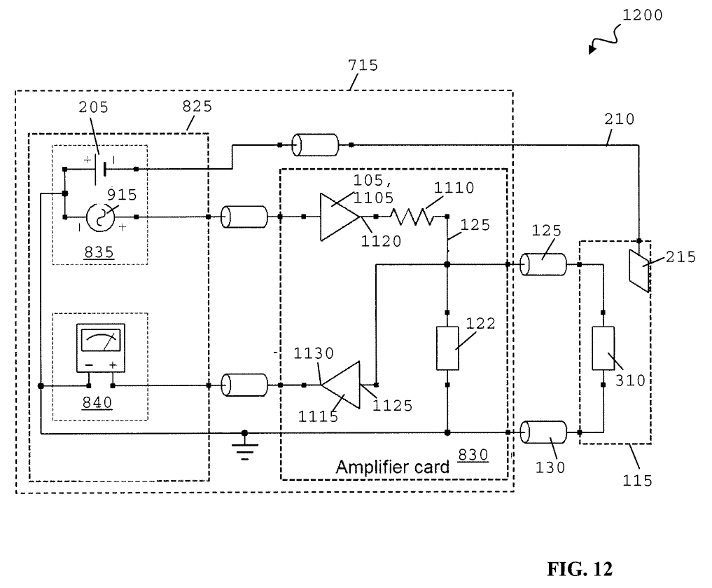

FIG. 12 is a schematic representation of an active filter 1200 of a measurement system for probing electrode/solution interfaces in systems such as system 200. In particular, active filter 1200 includes voltage supply 205, conductor 210, and reference electrode 215 so that electrode 140 can be placed at a desired potential relative to the potential of reference electrode 215.

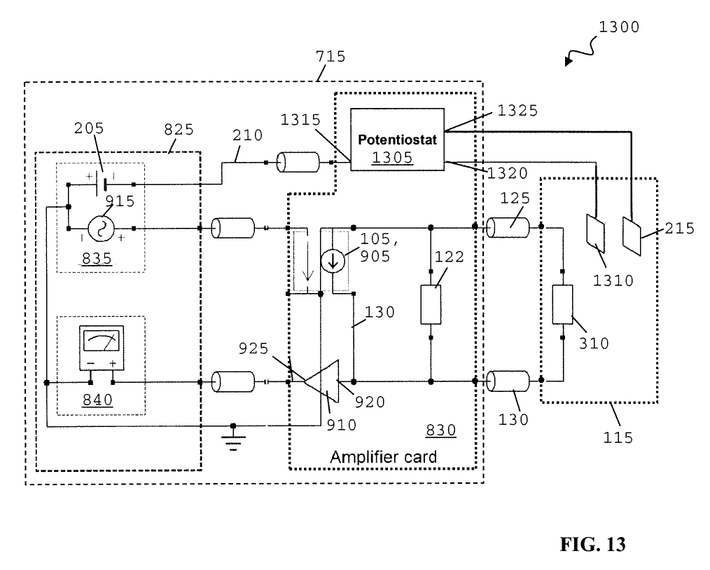

FIG. 13 is a schematic representation of an active filter 1300 of a measurement system for probing electrode/solution interfaces in systems such as system 200. Active filter 1300 includes a potentiostat 1305 and a counter electrode 1310. Potentiostat 1305 has an input 1315 and a pair of outputs 1320, 1325. Input 1315 of potentiostat 1305 is connected to conductor 210. Output 1320 of potentiostat 1305 is connected to counter electrode 1310. Output 1325 of potentiostat 1305 is connected to reference electrode 215.

The voltage applied to conductor 210 by voltage supply 205 can act as a control signal for potentiostat 1305. In particular, potentiostat 1305 includes an internal voltage source (not shown) that can place an impedance 310 at a desired potential relative to the potential of reference electrode 215 in solution 135 in response to the voltage applied to conductor 210 by voltage supply 205. Potentiostat 1305 can maintain impedance 310 at the desired potential by passing current through counter electrode 1310. Thus, although conductor 210 is not directly connected to reference electrode 215, the voltage on conductor 210 can participate in the placement of electrode 140 at a desired potential relative to the potential of reference electrode 215 in solution 135.

With potentiostat 1305 biasing impedance 310 using counter electrode 1310, impedance 310 generally does not include a counter electrode. Instead, impedance 310 can be formed, e.g., by interdigitated electrode pair 500.

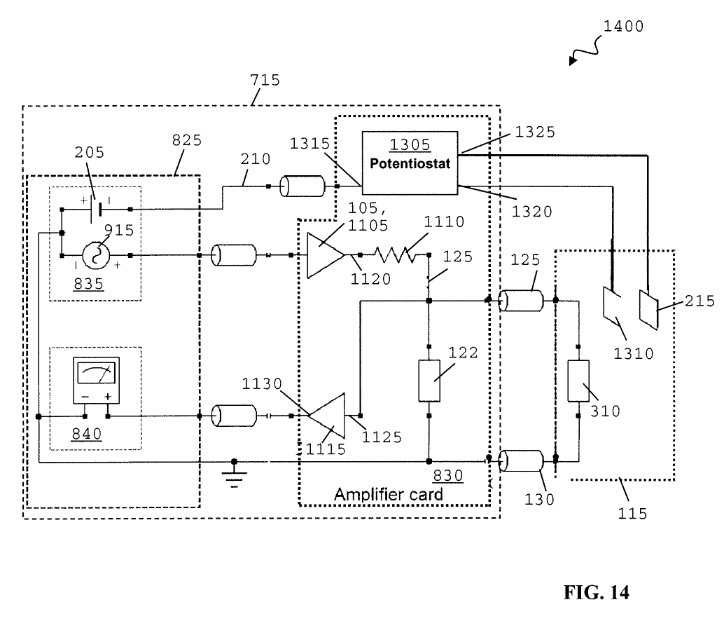

FIG. 14 is a schematic representation of a passive filter 1400 of a measurement system for probing electrode/solution interfaces in systems such as system 200. Passive filter 1400 includes potentiostat 1305 and counter electrode 1310. Once again, the the voltage applied to conductor 210 by voltage supply 205 can act as a control signal for potentiostat 1305 for placing electrode 140 at a desired potential relative to the potential of reference electrode 215 in solution 135.

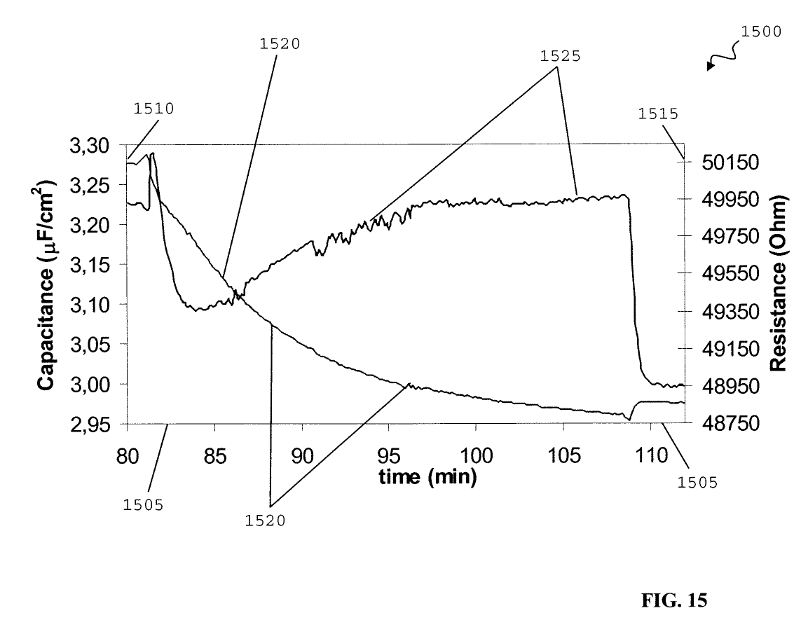

FIG. 15 is a graph 1500 that presents results of probing an electrode/solution interface. Graph 1500 can be presented to a user on a display screen in response to display instructions received from a data processing device. For example, graph 1500 can be presented in response to display instructions received from user interface module 805.

Graph 1500 was formed using a measurement system that includes passive filter. Graph 1500 characterizes the binding of 25 ug/ml of Mepf1 protein in 100 mM acetic buffer, 75 mM NaCl, pH 5.5 to electrodes modified with octylmercaptan by over night immersion in ethanolic solution, as described further in the empirical results section below.

Graph 1500 is a Cartesian graph and includes an x-axis 1505 and a pair of y-axes 1510, 1515. Position along x-axis 1505 indicates time. Position along y-axis 1510 indicates capacitance in microfarads per square centimeter. Position along y-axis 1515 indicates resistance in Ohms.

Graph 1500 also include a pair of traces 1520, 1525. Trace 1520 is metered along y-axis 1510 and represents a capacitive component of the impedance between the electrode and the conducting solution. Trace 1525 is metered along y-axis 1515 and represents a resistive component of the impedance between the electrode and the conducting solution. In particular, treating inductive impedance 305 as including a resistive component R_{L}, a capacitive component of the electrode solution interface (in this case, C₄₂₀) and a resistive component of the electrode solution interface (in this case, R₄₁₅) can be characterized as per Equations 9 and 10 and represented using traces 1520, 1525.

$$\begin{matrix}{Z}_{NET} = {Z}_{305} ‖ {Z}_{310} = {( \frac{1}{{R}_{L} + j ω L} + {( {R}_{405} + {( \frac{1}{{R}_{415}} + j ω {C}_{420} )}^{- 1} )}^{- 1} )}^{- 1} & Equation 9 \\ {( {( {Z}_{NET}^{- 1} - \frac{1}{{R}_{L} + j ω L} )}^{- 1} - {R}_{405} )}^{- 1} = \frac{1}{{R}_{415}} + j ω {C}_{420} & Equation 10\end{matrix}$$

As shown, as the capacitive component indicated by trace 1520 increases, the resistive component indicated by trace 1525 first spikes, then decreases rapidly, and then increases more gradually. The values in graph 1500, and Equations 9 and 10, account for the duplication of the interfaces in the pair of interdigitated electrodes.

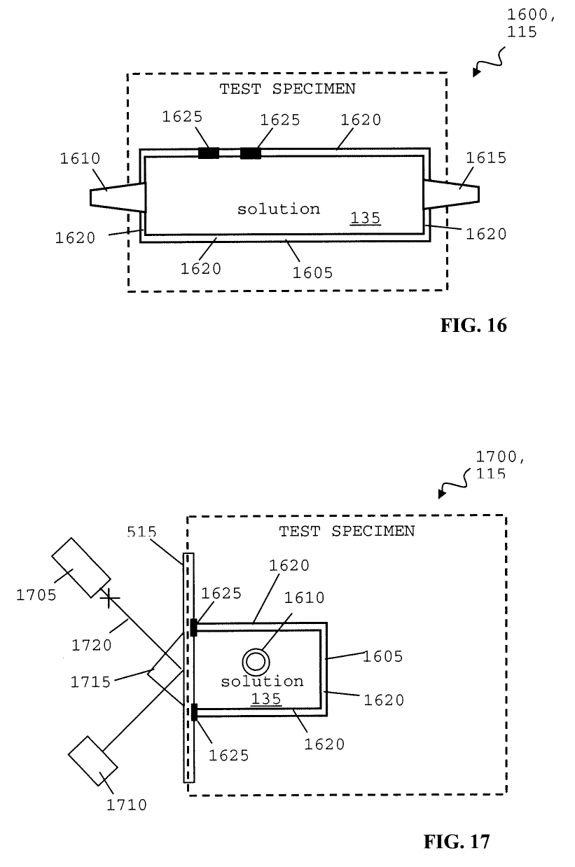

FIG. 16 is a schematic representation of a test specimen 1600 of a measurement system for probing electrode/solution interfaces in systems such as systems 100, 200. Test specimen 1600 can be used in place of test specimen 115 and includes a flow channel 1605, a fluid inlet 1610, and a fluid outlet 1615. Flow channel 1605 is defined by one or more walls 1620 that include one or more feedthroughs 1625. Feedthroughs 1625 can include conductors (such as conductors 125, 130, 210, 1320, 1325) that allow electrical contact to be made to electrodes within flow channel 1605.

Flow channel 1605 can conduct a flowing solution 135 across one or more electrode/solution interfaces 120 (not shown). For example, in some implementations, an interdigitated electrodes pair 500 can be upstream of reference electrode 215, which is in turn upstream of counter electrode 1310 when flow channel 1605 is used with active filter 1300 or passive filter 1400 of a measurement system 200.

FIG. 17 is a schematic representation of a test specimen 1700 of a measurement system for probing electrode/solution interfaces in systems such as systems 100, 200. Test specimen 1700 can be used in place of test specimen 115 and can include a flow cell, as shown. Test specimen 1700 also includes an electromagnetic radiation source 1705, an electromagnetic radiation detector 1710, and an electromagnetic radiation coupler 1715. Electromagnetic radiation source 1705 can be, e.g., a source of visible light or infrared radiation suitable for exciting surface plasmons in a material that supports surface plasmons, such as a gold or silver interdigitated electrodes pair 500 on substrate 515. Electromagnetic radiation detector 1710 is a detector of electromagnetic radiation 1720 generated by source 1705 and can be implemented as, e.g., a photodetector or the like. Electromagnetic radiation coupler 1715 is a device for coupling the electromagnetic radiation generated by source 1705 into substrate 515 so that the coupled electromagnetic radiation can interact with interdigitated electrodes pair 500 formed thereon. Electromagnetic radiation coupler 1715 can be a prism.

In operation, solution 135 can flow over interdigitated electrodes pair 500 on substrate 515. The net impedance between the interdigitated electrodes of pair 500 can be probed at the same time that electromagnetic radiation 1720 excites surface plasmons in the interdigitated electrodes. The position and intensity of plasmon absorption and emission can reflect the structure of electrode/solution interfaces (e.g., due to the adsorption of species at the surface of the interdigitated electrodes of pair 500) and can be determined using detector 1720. Thus, the electrode/solution interface can be probed using both impedometric and optical analytical techniques simultaneously.

### Empirical Results of Probing Electrode/Solution Interfaces

The systems and techniques described above can be used to probe a variety of different electrode/solution interfaces. For examples protein adsorption at an electrode/solution interface can be probed, antibody-antigen interactions at an electrode/solution interface can be probed, and structural differences in a protein film at an electrode/solution interface can be probed.

For example, serum protein adsorption at an electrode/solution interface can be probed. Serum protein adsorption is a key process in biomaterial research since the layer formed at the liquid-solid interface of implants dictates the later cellular response to the surface. The characteristics of an interface are thought to impact the amount of protein adsorption, the orientation of adsorbed proteins, and denaturation of the adsorbed proteins. For example, hydrophobic surfaces generally adsorb proteins more firmly, whereas proteins are adsorbed at hydrophilic surfaces more loosely.

In one investigation, interdigitated electrodes were submersed in a solution of 3-mercapto-1-propanol (MPOH) in ethanol and 1-propanethiol (MPCH_{3) i}n hexane. Serum was prepared from citrated blood plasma. Veronal buffered saline (VBS⁺⁺, pH 7.4) was used as a running buffer and for serum dilution (1:5). The MPCH₃ surface coated with aIgG was used as positive control due to its known ability to adsorb serum protein.

Serum protein adsorption on a hydrophilic surface was expected to be scarce. In this investigation, the MPOH surface displayed only a small decrease in capacitance after exposure to serum. In contrast, both the aIgG-coated surface and the MPCH₃ surface displayed a large change in capacitance after exposure to serum. By following the change in capacitance over time, it is evident that the adsorption kinetics on the two surfaces differs. In particular, nonspecific adsorption on the MPCH₃ surface was very fast and displayed a more linear kinetics. Adsorption onto the IgG-MPCH₃ surface reflects a combination of an initial nonspecific binding followed by the specific binding of IgG from serum. The described systems and techniques can thus be used to study protein adsorption kinetics.

As another example, antibody (anti-Hb)-antigen (Hb) interactions at an electrode/solution interface can be probed. An electrode that is coated with an antibody (Ab) layer generally has a stable impedance. When analyte binds to the adsorbed antibody, the impedance of the electrode/solution interfaces changes. The nature of the changes depends on the nature and coverage of the analyte.

In one investigation, interdigitated electrodes were functionalized by immobilizing anti-hemoglobin antibody on a self-assembled 3-mercaptopropionic acid monolayer via covalent coupling to the carboxymethyl endgroups of the monolayer using EDC/NHS chemistry. Unreacted sites at the monolayer were deactivated by injection of 100 mM ethanolamine at pH 8.5. A polyethylene glycol terminated thiol was used to block bare spots on the electrode surface.

The electrodes were exposed to Hb solutions in a concentration range from 1 to 100 μg/ml in 100 mM tris buffer at pH 7.0. A concentration dependent decrease in capacitance was observed upon Hb binding, which is consistent with a displacement of electrolyte from the surface. An increase in resistance was also observed. Interestingly, this effect was relatively higher at the lowest concentration, which may reflect some intrinsic property of the metalloprotein hemoglobin.

As another example, structural differences in a Mytilus edulis foot protein 1 (Mefp1) film at an electrode/solution interface can be probed. Mefp1 is able to adsorb to a wide range of surface, which is usually attributed to its relative high DOPA (3,4 di-hydroxyphenylalanine) content. Oxidation of DOPA to the reactive o-quinone yields strong bonds that contribute to the adhesive properties of Mefp1. However, DOPA also contributes to the cohesive properties of Mefp 1 by formations of internal di-DOPA cross-links. DOPA oxidation can be induced in several ways. For example, DOPA is auto-oxidized at >pH 7 and oxidation can be chemically induced by adding sodium periodate (NaIO₄). As another example, DOPA can form very strong complexes with metal ions such as copper.

In one investigation, interdigitated electrodes were submersed in a solution 1-octylmercaptan with a methyl end-group dissolved in ethanol for >12 h. Stock solution of Mefp1 (0.97 mg/ml in 1% citric acid) was diluted prior to injection to a concentration of 25 □g/ml in running buffer (100 mM Acetic buffer, 75 mM NaCl, pH 5.5). Oxidation and cross-linking of DOPA was induced either chemically using 1 mM NaIO₄, by increasing the buffer pH to 9 or by complex-formation with cupper (1 mM CuCl₂).

Protein adsorption to the electrode surface and sequential structure changes in the adsorbed protein film were followed in real-time. Oxidation and cross-linking of DOPA residues in a Mefp1 protein film yields different results depending on the integrity of the DOPA residues, namely, whether they are cross-linked intramolecular or if the DOPA residues are in complex formation with metal ions.

With chemical oxidation, using NaIO₄ as an oxidizer, DOPA residues are thought to be oxidized into the reactive o-quinone, which in turn can react and form di-DOPA cross-links with other DOPA residues within the protein. DOPA is also sensitive to pH and an increase in pH (>6) will induce auto-oxidation of DOPA, resulting in the same intramolecular cross-links. Copper however, is a strong metal chelator and can bind several DOPA residues. Both copper and sodium periodate can interact with an exposed gold surface and hence affect the capacitance. The results have therefore been interpreted as the change in capacitance (□cap) upon addition of an oxidizing agent to a surface with and without adsorbed Mefp1. Surface Plasmon Resonance detects the amount of adsorbed mass on the surface and was used to confirm that the Mefp1 protein film remained attached on the surface upon oxidation. By combining the probing of the electrode/solution interface with quart crystal microbalance techniques, oxidations of a Mefp1 protein film using different oxidizing agents can be discriminated.

NaIO₄ induced or auto-oxidized cross-linking of DOPA yields intramolecular cross-links and contracts the protein film. A patchier protein film structure results and the underlying surface is exposed. The surface becomes less isolated from solution and an increase in capacitance is observed. Once a Mefp-1 protein film is formed on the surface, the sodium periodate induced change in capacitance (□cap) is significantly larger than for the bare surface alone. The change in capacitance upon sodium periodate addition and the change in capacitance upon Mefp1 adsorption is correlated. As expected, the results show that the more protein adsorbed to the surface, the larger the induced change in capacitance upon oxidation. Auto-oxidation with increasing pH induces a smaller change in surface capacitance. An adsorbed Mefp1 protein film on a hydrophobic surface is thought to form a very viscous film. With increases in pH of the surrounding buffer, some DOPA residues will start to auto-oxidize. However, it is likely that patches of more acidic buffer remain trapped in the viscous protein film leaving some DOPA intact. A sequential addition of sodium periodate results in an additional capacitance increase, although the total capacitance change is smaller than for when sodium periodate is used directly on the Mefp1 protein film.

Copper can bind one or more DOPA residue in a complex formation. Such intermolecular cross-links can exist between DOPA-groups from different proteins. In these cases, the adsorbed protein film does not contract or experience the same reduction of viscosity as when intramolecular cross-links are formed. Quartz crystal microbalance measurements show a decrease in dissipation upon copper addition to a Mefp1 coated surface. However, the corresponding results of impedance probing of the electrode/solution interface show no significant difference in surface capacitance between exposure of a thiol-coated gold surface or a Mefp1 coated surface to copper. DOPA residues involved in complex formation with copper do not form cross-links that contract the film and make it lose its viscous properties. Rather the protein film remains over the surface, keeping it isolated from solution. The surface of the interface remains unchanged. Further, a sequential addition of sodium periodate to the cupper-cross-linked protein film results in an additional increase in capacitance. Copper induced oxidation may be less effective than chemically induced oxidation due to physical constraints within the protein film. Also, unoxidized DOPA may still be available within the protein film. It is not likely that the strong Cu-DOPA interaction substitutes for di-DOPA cross-links, which is supported by the fact that sequential addition of NaIO₄ does not yield the same increase in capacitance as when NaIO₄ is initially used.

The combined probing of the electrode/solution interface and quartz crystal microbalance measurements indicate that changes in the Mefp1 film are not identical when different oxidizing agents are used. Quartz crystal microbalance measurements indicate that, upon oxidation with pH, copper, or sodium periodate, there is a decrease in dissipation. The size of this decrease is dependent on the oxidizing agent. From these results alone, very little can be said about the integrity of the DOPA residues, e.g., whether they are in the form of di-DOPA cross-links or if they are in complex formation with DOPA. On the other hand, the results of probing of the electrode/solution interface show that the change in surface capacitance differs depending on the choice of oxidizing agent. Addition of NaIO₄ or an increase of pH will increase the capacitance of a Mefp1 of the interface. The exposure of a Mefp1 protein film to copper ions shows no significant change in surface capacitance. Nevertheless, quartz crystal microbalance measurements indicate that the protein film loses some of its viscous properties. The unchanged capacitance indicates that the protein film retains the same isolating properties. The interfacial capacitance is dependent on the charge transport over the surface and a more porous film is the result of NaIO₄— or pH-induced oxidation of a Mefp1 film in which the capacitance is increased. A protein film with intermolecular cross-links remains isolating.

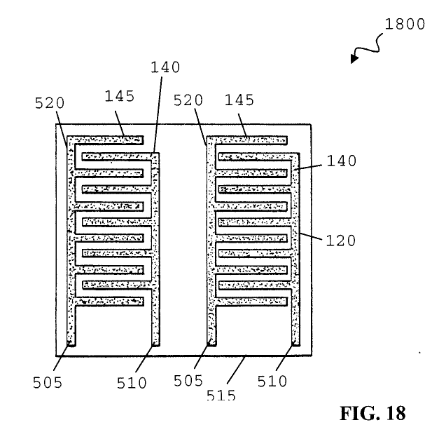

A number of implementations have been described. Nevertheless, it will be understood that various modifications may be made. For example, as shown in FIG. 18, an array 1800 of two or more pairs of interdigitated electrodes can be used to probe electrode/solution interfaces in systems such as systems 100, 200. In such arrays, the different electrode/solution interfaces 140, 520 can be functionalized or otherwise treated differently and probing of multiple electrode/solution interfaces 140, 520 can proceed in parallel. For example, the remainder of the probing system can be reproduced and/or multiple electrode/solution interfaces 140, 520 can be addressed in series by a single system for probing, e.g., using multiplexing or other techniques.

Accordingly, other implementations are within the scope of the following claims.

What is claimed is:

1. A device comprising:
a time variable source of power configured to output power that varies in time over a pair of output conductors;
an electrode connected to a first of the conductors, the electrode configured to be submersed in a conducting solution and form an interface with the conducting solution;
an extrinsic inductive impedance connected between the pair of output conductors; and
an impedance sensor connected to one or both of the output conductors and configured to measure net impedance between the pair of output conductors based on a known current or voltage output by the time variable power output, wherein the measured net impedance includes the extrinsic inductive impedance and an impedance of the interface.

2. The device of claim 1, further comprising:
a reference electrode; and
a voltage source connected to bias the electrode relative to the reference electrode.

3. The device of claim 1, further comprising a potentiostat to bias the electrode.

4. The device of claim 1, further comprising a controller configured to perform operations, the operations comprising:
setting a frequency of the time variable power output to the two or more frequencies; and
receiving, from the impedance sensor, information characterizing the impedance of the time variable power output at the two or more frequencies.

5. The device of claim 2, wherein the operations of the controller further comprise:
modeling impedance of the interface between the electrode and the conducting solution considering the impedance between the electrode and the conducting solution to be in parallel with impedance of the extrinsic inductive impedance;
characterizing a capacitive component of the impedance between the electrode and the conducting solution using the impedance between the electrode and the conducting solution; and
outputting a characterization of the capacitive component.

6. The device of claim 1, wherein the time variable source of power comprises a voltage or current source configured to output a voltage or a current at frequencies below 100 kHz.

7. The device of claim 1, wherein the time variable source of power comprises a current source programmable to output a known current.

8. The device of claim 7, wherein the impedance sensor comprises a voltammeter connected to sense a voltage resulting from a flow of the time variable current through the impedance.

9. The device of claim 1, wherein the time variable source of power comprises a voltage source programmable to output a known voltage.

10. The device of claim 9, wherein the impedance sensor comprises a voltammeter connected to sense a voltage across the impedance.

11. The device of claim 1, wherein:
the device further comprises the conducting solution and a contact between a second of the conductors and the solution;
the electrode is submersed in the conducting solution; and
the measured impedance excludes a bulk solution capacitance of the conducting solution.

12. A system comprising:
a display screen; and
one or more data processing devices programmed to interact with the display screen and to perform operations, the operations comprising:
receiving results of probing an electrode/solution interface using an electrical signal, wherein the electrode/solution interface was in parallel with an extrinsic inductive impedance during the probing;
modeling impedance of the electrode/solution interface considering the impedance of the electrode/solution interface to be in parallel with impedance of the extrinsic inductive impedance;
characterizing a capacitive component or a resistive component of the electrode/solution interface using the impedance of the electrode/solution interface; and
displaying a characterization of the capacitive component or the resistive component of the electrode/solution interface on the display screen.

13. The system of claim 12, wherein the operations further comprise probing the electrode/solution interface.

14. The system of claim 13, wherein probing the electrode/solution interface comprises applying a potential referenced to a reference electrode to the electrode forming the electrode/solution interface.

15. The system of claim 12, wherein modeling impedance of the electrode/solution interface comprises ignoring bulk solution capacitance of the solution forming the electrode/solution interface.

16. The system of claim 12, wherein receiving the results of probing comprises receiving results characterizing impedance of the electrode/solution interface at two or more frequencies of the electrical signal.

17. The system of claim 12, wherein receiving the results of probing comprising receiving results characterizing a voltage across the electrode/solution interface in parallel with the extrinsic inductive impedance when a known time varying current is driven therethrough.

18. A method comprising:
receiving results of probing an interface between an electrode and a conducting solution, the results including measurements of an impedance of the interface in parallel with an extrinsic inductive impedance;
characterizing a capacitive component or a resistive component of the interface using a model that includes the impedance of the interface in parallel with an inductance of the extrinsic inductive impedance; and
outputting a characterization of the capacitive component or the resistive component.

19. The method of claim 18, wherein characterizing the capacitive component or the resistive component of the interface comprises ignoring a bulk solution capacitance of the conducting solution.

20. The method of claim 18, wherein receiving the results of probing the interface comprises receiving measurements of the impedance when a known current flows through the interface in parallel with the extrinsic inductive impedance.

21. The method of claim 18, wherein receiving the results of probing the interface comprises receiving measurements of the impedance with the electrode held in the conducting solution at a voltage relative to a reference electrode in the conducting solution.
